(19) United States
(12) Patent Application Publication
(10) Pub. No.: US 2008/0002472 A1
(43) Pub. Date: Jan. 3, 2008

(54) Controller for fuel cell in standby mode or no load condition

(75) Inventors: Zeev Aleyraz, St. Herzeliyya (IL); Shemuel Gal, St. Hadera (IL); Avi Amsili, St. Nes Ziona (IL); Guy Picha, St. Givat Shmuel (IL)

Correspondence Address: GREENBLUM & BERNSTEIN, P.L.C., 1950 ROLAND CLARKE PLACE, RESTON, VA, 20191, US

(73) Assignee: More Energy, Ltd., Lod (IL)

(21) Appl. No.: 11/476,561

(22) Filed: Jun. 29, 2006

(51) Int. Cl. G11C 11/34; G11C 16/04

(52) U.S. Cl. 365/185.19

(57) ABSTRACT

Process and apparatus for controlling a fuel cell. The process includes drawing a pulse from a fuel cell in one of a standby mode or no load condition. The pulse is one of a power, current, and voltage pulse. The apparatus includes a field effect transistor arranged to selectively couple a resistance to fuel cell to draw current from the fuel cell, and a timer defining a pulse, during which the field effect transistor couples the resistance to the fuel cell to draw current from the fuel cell. The instant abstract is neither intended to define the invention disclosed in this specification nor intended to limit the scope of the invention in any way.

### BACKGROUND OF THE INVENTION

1. Field of the Invention

The present invention is directed to controller for fuel cell in standby mode.

2. Discussion of Background Information

As a direct hydride fuel cell (DHFC) rests in standby mode, i.e., no power being drawn, the system may slowly lose start up power such that when a current is drawn, the power available is lower than if the cell did not go into standby mode. As the device is operated, the available power level will eventually return to the desired level, but this behavior is not desirous.

It believed that membrane blocking may be an issue for standby operation of DHFCs, especially when the fuel is a suspension or the spent fuel forms precipitated salts. In periods of inactivity and without external sources of mixing, e.g., from transport, it is believed that salts can precipitate on the anode, cathode, or the membrane, such as a mesh membrane as disclosed by commonly owned U.S. application Ser. No. 10/941,020 filed Sep. 15, 2004, the disclosure of which is expressly incorporated by reference herein in its entirety.

### SUMMARY OF THE INVENTION

The present invention is directed to a method of improving fuel standby performance for DHFCs. Moreover, the present invention improves the standby performance of DHFCs utilized in conjunction with mesh membrane fuel cells, as disclosed in U.S. application Ser. No. 10/941,020.

To prevent blocking, a control system according to the present invention regularly activates the fuel cell, which causes fluidic and ionic movement that prevents or limits salt blocking.

According to the invention, a power draw pulse and pulse timing are adjusted to the fuel cell design configuration. It is advantageous to limit the pulse time and intensity and to increase the time between pulses to conserve energy, so the pulse will preferably be a minimum necessary to ensure limited or no startup power degradation under all targeted operating conditions.

The controller operates in either a time domain or based on measured cell performance. The controller can be tuned to the fuel cell configuration by using a specific interval time, pulse time, and pulse intensity. Moreover, multiple rapid pulses or pulse nesting can be utilized.

Other exemplary embodiments and advantages of the present invention may be ascertained by reviewing the present disclosure and the accompanying drawing.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 illustrates a block diagram of the controller for a fuel cell in either standby mode or no load condition according to the invention;

FIG. 2 illustrates a pulse for drawing current from the fuel cell, including a plurality of sub-pulses nested with the pulse;

FIG. 3 schematically illustrates the controller in accordance with the invention;

FIG. 4 schematically illustrates an alternative arrangement for the controller depicted in Figure in accordance with the invention;

FIG. 5 schematically illustrates an example of the reference and current source depicted in FIG. 4;

FIG. 6 schematically illustrates an example of the tuneref unit depicted in FIG. 5;

FIG. 7 schematically illustrates an example of the restart block depicted in FIG. 4;

FIG. 8 schematically illustrates an exemplary embodiment of the initializer block depicted in FIG. 4;

FIG. 9 schematically illustrates an exemplary embodiment of the drive block depicted in FIG. 4;

FIG. 10 schematically illustrates an exemplary embodiment of the clock main block depicted in FIG. 4;

FIG. 11 schematically illustrates an exemplary embodiment of the clock doubler block depicted in FIG. 4;

FIG. 12 schematically illustrates an exemplary embodiment of voltage boost converter block depicted in FIG. 4;

FIG. 13 schematically illustrates an exemplary embodiment of ClkLv unit block depicted in FIG. 12;

FIG. 14 schematically illustrates an exemplary embodiment of ClkHv unit depicted in FIG. 12;

FIG. 15 schematically illustrates an exemplary embodiment of the AdDelta cells depicted in FIG. 14;

FIG. 16 schematically illustrates an exemplary embodiment of the step up block depicted in FIG. 12;

FIG. 17 schematically illustrates an exemplary embodiment of SnsHiV unit depicted in FIG. 12;

FIG. 18 schematically illustrates an exemplary embodiment of the test A unit depicted in FIG. 4;

FIG. 19 schematically illustrates an exemplary embodiment of the TstSlct unit depicted in FIG. 18;

FIG. 20 schematically illustrates an exemplary embodiment of Prtct unit depicted in FIG. 18;

FIG. 21 schematically illustrates an exemplary embodiment of TstDrv unit depicted in FIG. 18; and

FIG. 22 schematically illustrates the controller depicted in FIG. 4.

### DETAILED DESCRIPTION OF THE PRESENT INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the several forms of the present invention may be embodied in practice.

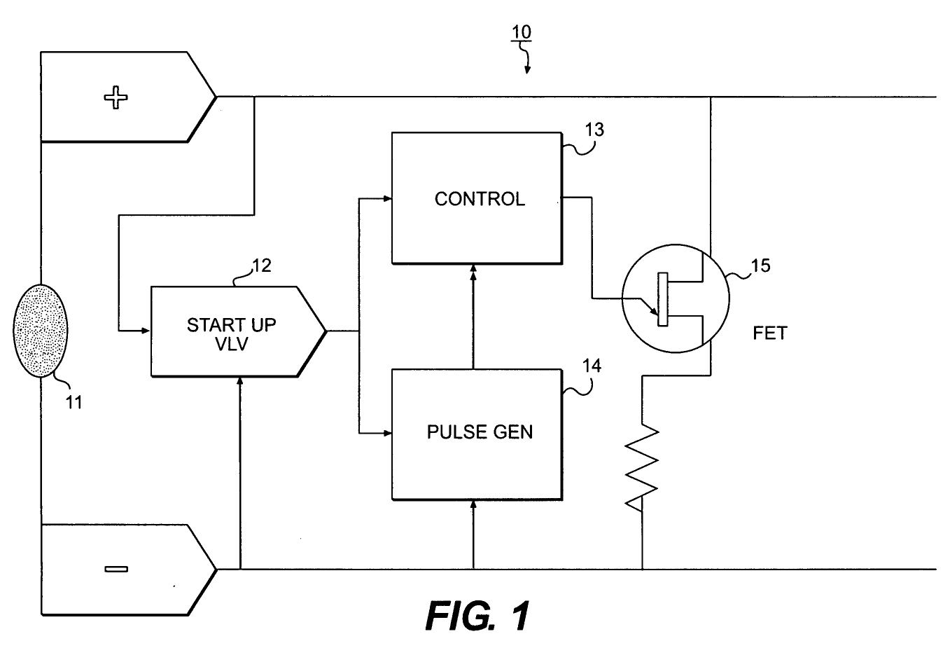

The present invention is directed to a controller for a fuel cell, e.g., a DHFC, and a process for controlling a fuel cell so that startup power is not lost while the fuel cell rests in standby mode. Of course, it is understood that other fuel cell chemistries can be utilized without departing from the scope and spirit of the invention, e.g., PEM, DMFC, AFC, etc. A block diagram of controller 10 is illustrated in FIG. 1. Controller 10 is coupled to fuel cell 11, which can be a DHFC, and preferably a DHFC used in conjunction with a mesh membrane in accordance with U.S. application Ser. No. 10/941,020. Controller 10 is provided to draw current, i.e., current pulses, from fuel cell 11 when fuel cell 11 is in standby mode or under a no load condition. Controller 10 is arranged to operate when the input voltage exceeds 0.8 V and stops when fuel cell voltage drops below 0.75 V.

The output voltage of fuel cell 11 at the time controller 10 is activated, e.g., greater than 0.8 V, is increased in a start up device 12, which is composed of a boost converter and start oscillator. The boost converter converts the low input cell voltage to a level sufficient to act as a supply voltage for the functions of controller 10, e.g., about 2.7 V. Because the boost start voltage is about 0.85 V, the start up converter oscillator is utilized to reduce the start up to 0.6 V.

Start up device 12 is coupled to a control 13, which monitors fuel cell 11 to determine whether fuel cell 11 is in stand by mode or in a no load condition, and to a pulse generator 14, which can be composed of, e.g., a timer activator, an oscillator, and a timer. Moreover, pulse generator 14 can be coupled to control 13 so that control 13 can produce a desired pulse train to a field effect transistor (FET) 15, e.g., a metal oxide semiconductor FET (MOSFET), which provides the desired current draw on fuel cell 11.

Control 13 can include a comparator and reference which compares the input fuel cell voltage to a reference voltage. When the input voltage reaches 0.8 V, control 13 recognizes a stand by or no load condition, and then actuates pulse generator 14. Moreover, a hysteresis resistor is used to avoid oscillations, so that when the input voltage drops below 0.7 V, pulse generator 14 can be deactivated by control 13.

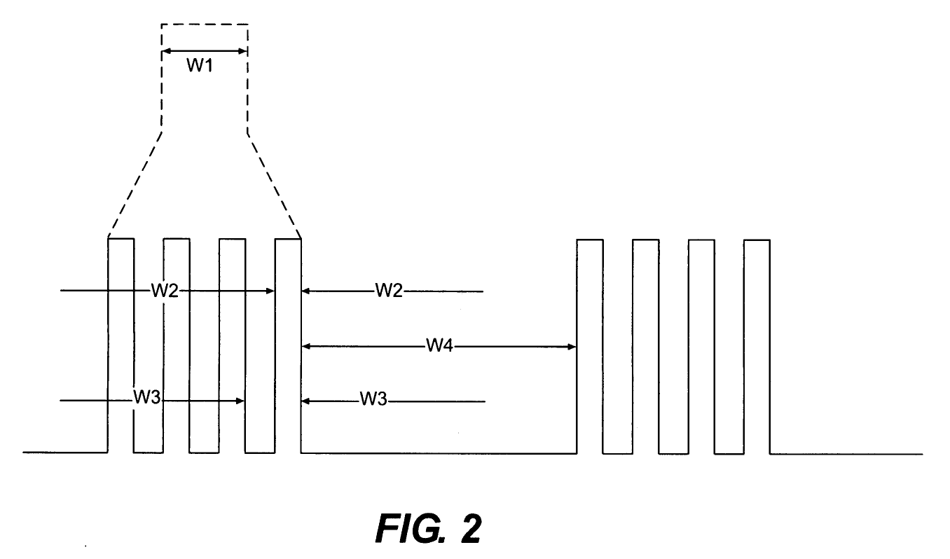

When pulse generator 14 is activated by control 13, the output of control 13 changes the timer activator from high to low. The output of the timer activator is coupled to a reset pin of the timer, which starts the timer counting. The timer is driven by the oscillator, e.g., a simple operational amplifier with a positive feedback arranged to provide a square wave form having a 50% duty cycle and a frequency of 0.5 Hz. The square wave can be supplied to the timer clock pin. The output of the timer is coupled to FET 15 to activate FET 15 for a predetermined period to create the pulse train. As shown in FIG. 2, the timer defines a pulse, e.g., a current, voltage, or power pulse, of a predetermined duration W1, between 0.1-30 minutes, e.g., 32 seconds, and defines a predetermined (rest) period between pulses W4, between 1 second to one week, e.g., 2.27 hours. By way of example, the current pulse can be about 1.7 A.

However, because a device cannot shut down until the end of a pulse, it has been found to be advantageous to utilize nested or sub-pulses in lieu of the single pulse, as described above. Thus, as is further illustrated in FIG. 2, instead of defining a single pulse width W1, e.g., 32 seconds, the timer can instead define a plurality of pulses, e.g., four pulses having a pulse width W2, between 0 and W1, and a period between pulses of W3, e.g., between 0 and W1. Moreover, the period of W4 can be maintained between the nested or sub-pulses.

As noted above, the timer activates FET 15, i.e., drives FET 15 to saturation, to connect a suitable resistance to fuel cell 11 to draw current from fuel cell 11. The resistance draws, e.g., 1 amp, but it is contemplated to optionally draw 2 and/or 3 amps.

While the controller 10 is operational upon control 13 sensing a voltage level greater than 0.8 V, controller 10 can also be operated in a time domain (constant) mode, such that, when fuel cell 11 goes into stand by mode, a timer begins a count, and, if remaining in stand by mode at the end of the count, e.g., 12 hours, a pulse of predetermined width can be generated, e.g., 3 minutes, in order to draw current from fuel cell 11. Again, instead of a 3 minute single pulse, nested or sub-pulses within the pulse can be generated.

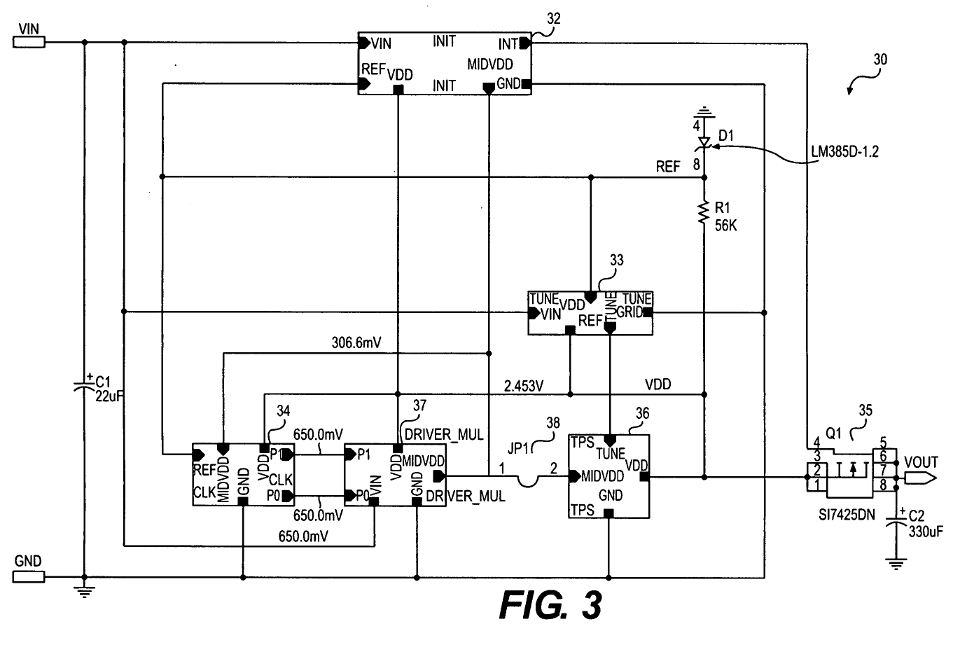

A schematic illustration of the controller 30 of the instant invention is shown in FIG. 3. The fuel cell under is coupled between contacts Vin and gnd. As illustrated, a capacitor C1 is arranged in parallel to the fuel cell. Further, boost converter and start oscillator 32 can be formed by conventionally available units or integrated circuits, as can comparator 33. As discussed above, the output of comparator 33 is coupled to a timer activator 36, which can be formed by conventionally available elements or integrated circuits, to activate timer 37, which defines the pulse train for drawing current from the fuel cell through FET 35. It is noted that activate timer 37 can be formed with conventionally available elements and includes various conventionally available switching block units or integrated circuits. Further, oscillator 34, provides the clock for operating clock 37 and can be formed by conventional elements or integrated circuits. Further, it is noted that the pulse's duration, the cycle time, and the peak current can be changed, e.g., by optionally replacing the jumpers 38.

It is noted that the circuits depicted in FIG. 3 is for the purpose of illustration and should not be considered as limiting. Thus, is it to be understood that other circuits and arrangements for monitoring the standby mode/no load condition of a fuel cell and for drawing an intermittent pulse from the fuel cell in order to relieve membrane blocking in accordance with the invention can be utilized without departing from the scope and spirit of the invention.

Moreover, it is contemplated that controller 10 can be integrated onto a single chip, which is either fixed or programmable, and can be built into or external to the fuel cell. Moreover, the chip on which controller 10 is integrated can include other controllers or converters.

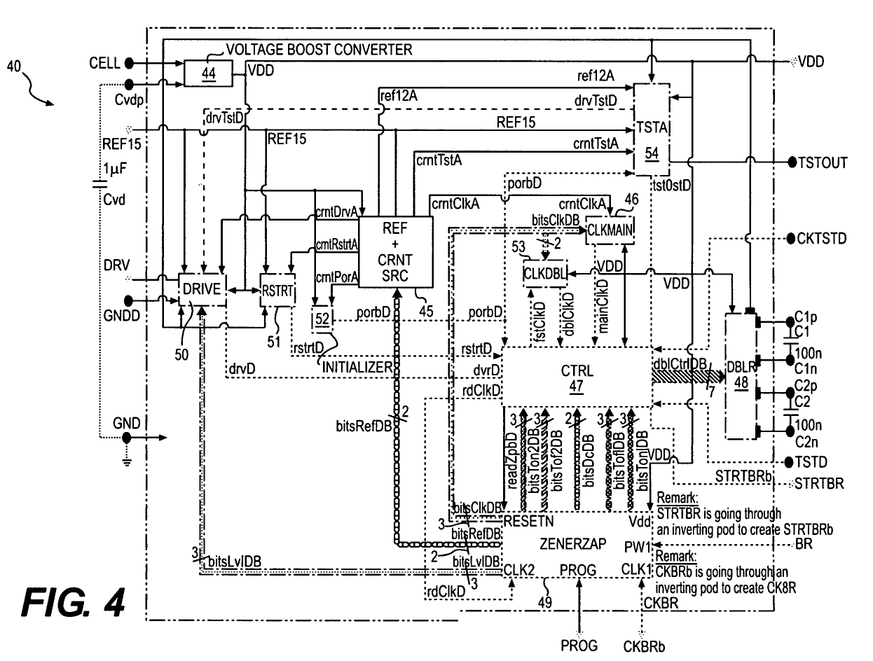

An alternative to the arrangement illustrated in FIG. 1 is shown in FIG. 4. In particular, controller 40 is designed to be coupled to a fuel cell, which can be a DHFC, and preferably a DHFC used in conjunction with a mesh membrane in accordance with U.S. application Ser. No. 10/941,020, at terminals 42 and 43. Fuel cell connection terminal 42 is coupled to a voltage boost converter 44 to increase the low cell voltage to produce a voltage Vdd to enable starting operation of the controller 40. Voltage Vdd is utilized for powering and operating the other blocks within controller 40. As shown, voltage boost converter 44 is coupled to reference and current source 45, which delivers a tunable buffered reference voltage of, e.g., 1.5 V, and all current sources for controller 40.

Reference and current source 45 forwards a signal to main clock 46, which creates the main clock for the system that runs at nominal frequency of, e.g., 8 kHz with 10% accuracy. Main clock 46 is coupled to control 47, which is arranged to control the various units of controller 40. Control 47 is coupled to forward a clock signal to zener zap block 49, which contains zener memory circuits and associated read/write controls, and zener zap block 49 in turn is coupled to forward signals to control 47 via a number of digital zap buses. Control 47 is also coupled to drive 50, which drives the fuel voltage to a predefined level, and to doubler 48, which charges the Vdd line capacitor, during normal operation, with 3 times the fuel cell voltage, and during start-up, when zaps are read and when drive 50 is activated, with 4 times the fuel cell voltage. Doubler 48, which can be composed of all FETs and their drivers, is an analog structure that operates the power of controller 40 in response to a command from control 47 to deliver 3 or 4 times the cell voltage. Zener zap block 49 is also coupled to drive 50, reference and current source 45, main clock 46, and clock doubler 53 through digital zap buses. Clock doubler 53 runs at a low power nominal frequency of, e.g., 8 kHz, and at a high power nominal frequency of, e.g., 56 kHz, at start-up when zaps are read and drive 50 is activated. Clock doubler 53 starts to operate at very low voltage.

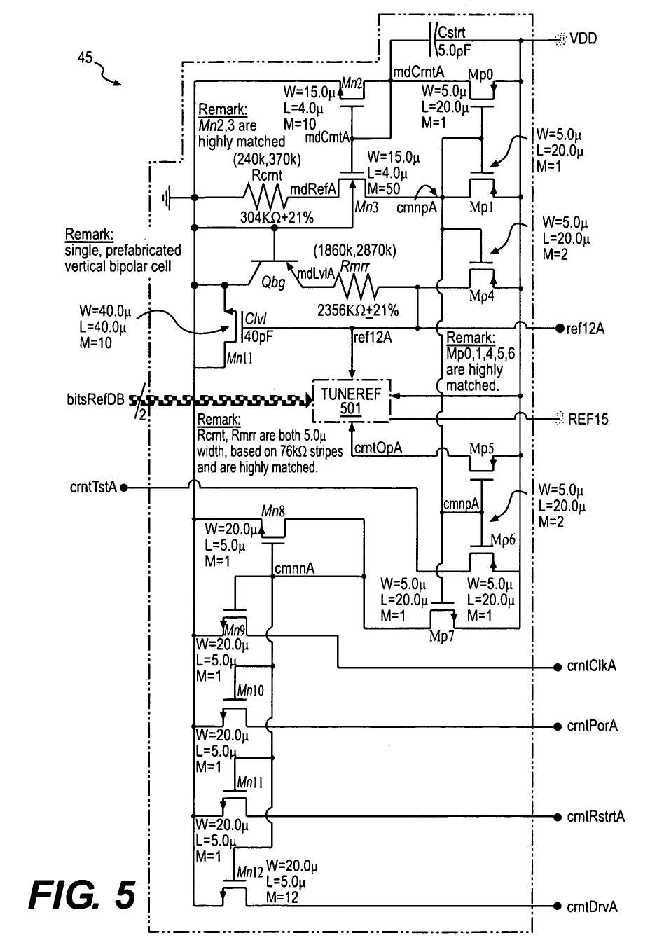

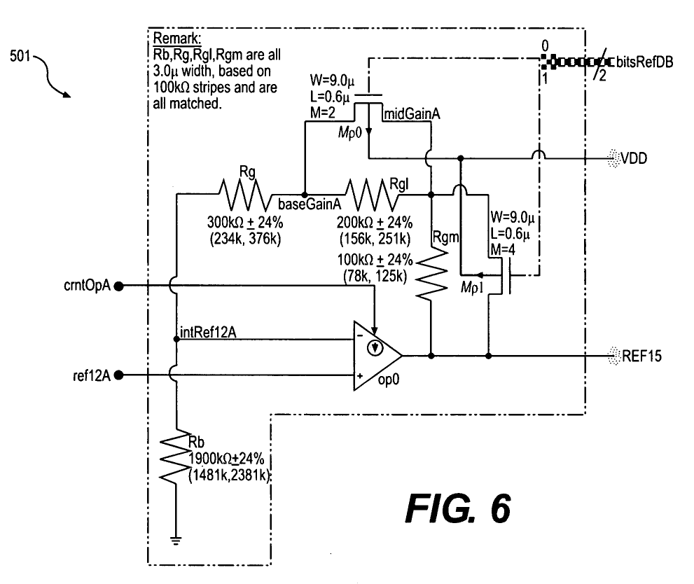

As shown in greater detail in FIG. 5, reference and current source 45, which can be formed, e.g., as a single prefabricated vertical bipolar cell, is responsible for unbuffered reference voltage ref12A and buffered tuned voltage REF15. Tuneref unit 501 is a buffer arranged to buffer line REF 15. The output of tuneref unit 51 (REF 15) is programmed more accurately through the use of zener bits from zener zap 49. An exemplary arrangement of tuneref unit 501 is illustrated in FIG. 6. Reference and current source 45 is also responsible for delivering all current sources of controller 40. To ensure proper operation, reference and current source 45 is checked to ensure Vdd is within a range of, e.g., 1.6 V-3.0 V, with a load over ref12A of, e.g., 2 pF, and a load over REF15 of, e.g., 6.0 pF/1.5 MΩ. All checks use high capacitance corner.

Reference input Ref15 provides a reference signal to drive 50 and restart 51. Restart 51 monitors fuel cell voltage and forwards a restart signal to control 47 when a load is detected. Drive 50 and restart 51 are also coupled to receive a signal from doubler 48. Further, initializer 52, which is coupled to reference and current source 45 and the output of voltage boost converter 44, is arranged to initialize all digital elements of controller 40 during start-up while waiting for Vdd to get to about 2.4 V through control 47. The test A unit 54 tests the various connections to ensure proper operation of controller 40.

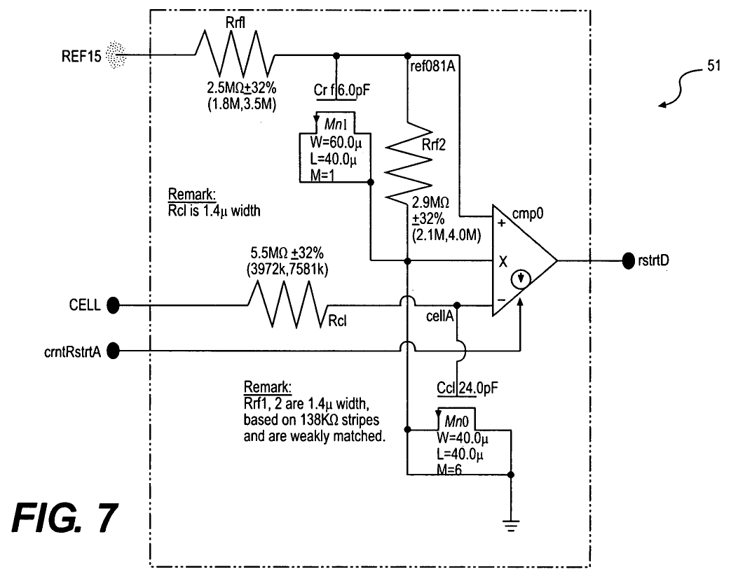

Restart 51 is responsible for detecting when cell voltage drops below, e.g., 0.81 V (4% accuracy) for about 100 μsec. An exemplary configuration of restart 51 is illustrated in FIG. 7. In this embodiment, restart 51 can be checked to respond to a 500 Hz square wave with range [0.87 V, 0.75V], when a negative pulse is either 10 μsec or 500 μsec. Further, all runs can be checked for low capacitance and high β processes.

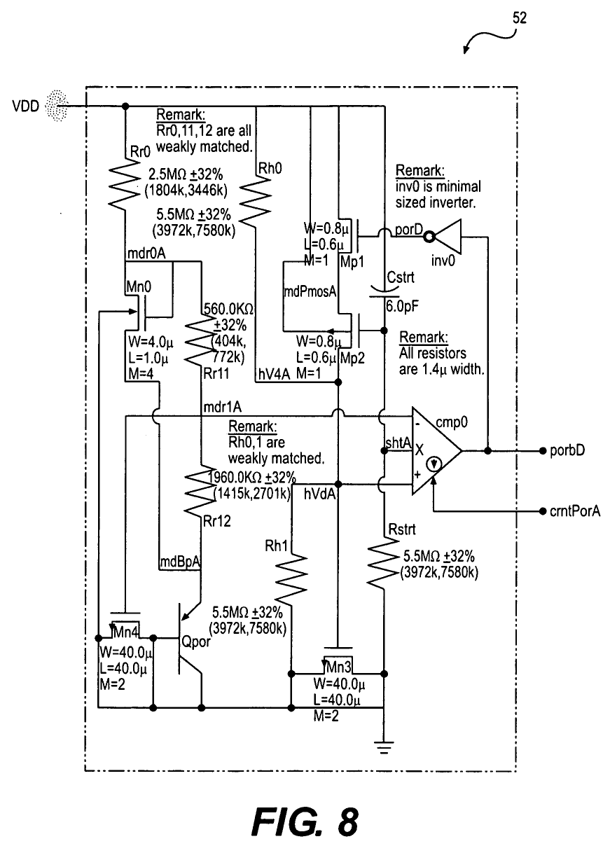

Initializer 52 is configured to initialize digital states in controller 40 and detect the first time Vdd reaches, e.g., about 2.5 V. An exemplary embodiment of initializer 52 is shown in FIG. 8, and is configured so that, after the initial stage, where Vdd starts at, e.g., about 1.3 V and the output of initializer 52 is set low (porbD=0). As discussed above, doubler 48 increases the voltage over Vdd, and this increasing continues until initializer 52 detects Vdd has reached 2.5 V, which is a voltage sufficient for reading zener zaps. When Vdd achieves 2.5 V, the output of initializer 52 is set high (porbD=1). To ensure proper operation, initializer 51 is checked to ensure a load of, e.g., 4.0 pF, and that Vdd quickly rises to 1.2 V and then slowly rises to 3.0 V. The measured parameter is the activating voltage.

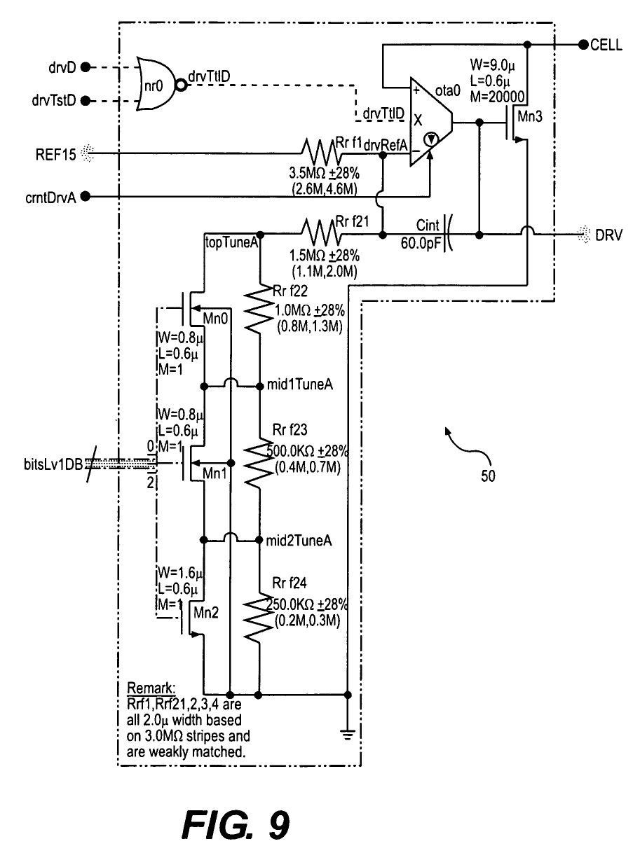

An exemplary detailed illustration of drive 50 is shown in FIG. 9. As shown, drive 50 can be configured as an open drain driver to drop cell voltage to a predefined voltage. Further, as it is configured to support external field effect transistors (FETs), drive 50 should exhibit a very stable loop. Due to the nature of the open drain driver, it should be checked in time domain and exhibit minor undershoot, e.g., 10%, in the worst case. In the exemplary embodiment, drive 50 is measured with, e.g., Vdd=3.8 (cell voltage) and an additional load of 4 nF at output DRV, which is provided for external FET connection. Moreover, drive 50 is checked at cell conditions of, e.g., 0.85 V-1.0 Ω/9.5 V-1.5 Ω.

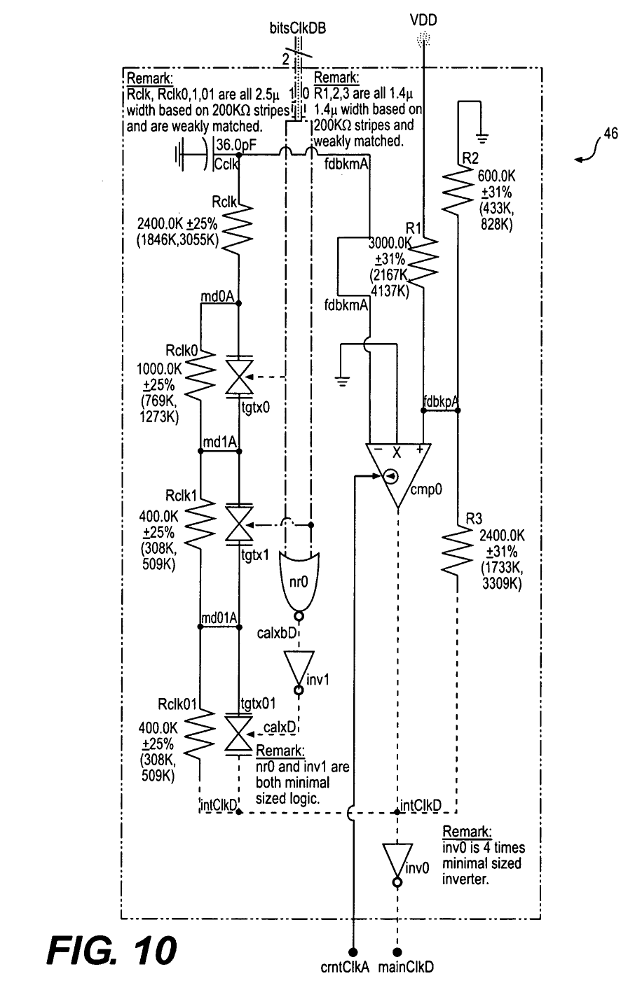

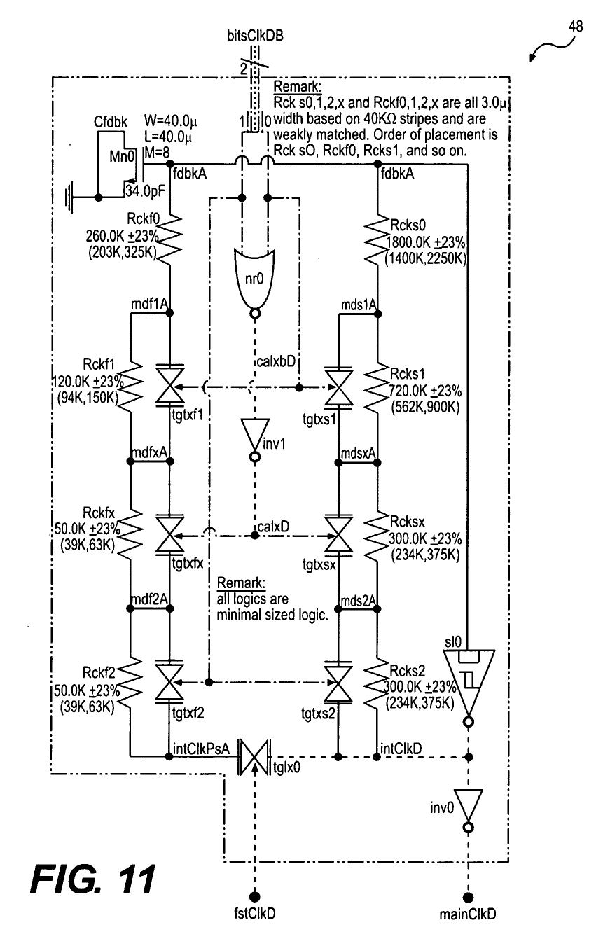

An exemplary embodiment of clock main 46 is depicted in FIG. 10. Further, clock doubler 53 is shown in greater detail in FIG. 11. Clock doubler 53 is a tunable system clock that has a double frequency option, which can run at a nominal fast frequency of 56 kHz (fstClkD=1) or at a nominal slow frequency of 8 kHz (fstClkD=0). As shown, clock doubler 53 uses the same tuning bits (bitsClkDR) as the clock main 46 generated by zener zap 49. Clock doubler 53 is checked with reference and current source 45 with hB bipolar option for Vdd in a range of 1.6 V-3.0 V with a load of 2 pF.

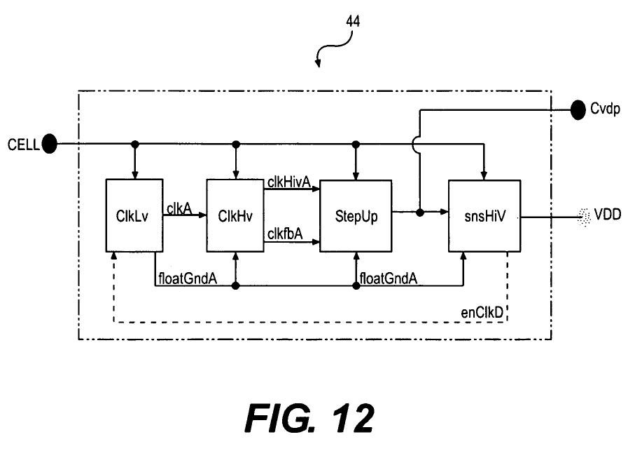

Voltage boost converter 44, an exemplary embodiment of which is shown in greater detail in FIG. 12, is a low voltage block operated from 0.85 V. As noted above voltage boost converter 44 takes the cell voltage and charge pumps the Cvd voltage capacitor to a voltage higher than the cell to enable safe operation, e.g., about 1.3 V nominal. When voltage boost converter 44 detects that the Cvdp has reached the desired voltage for operation, Cvdp is shorted to Vdd to operate the circuit, and voltage boost converter 44 is then shut down.

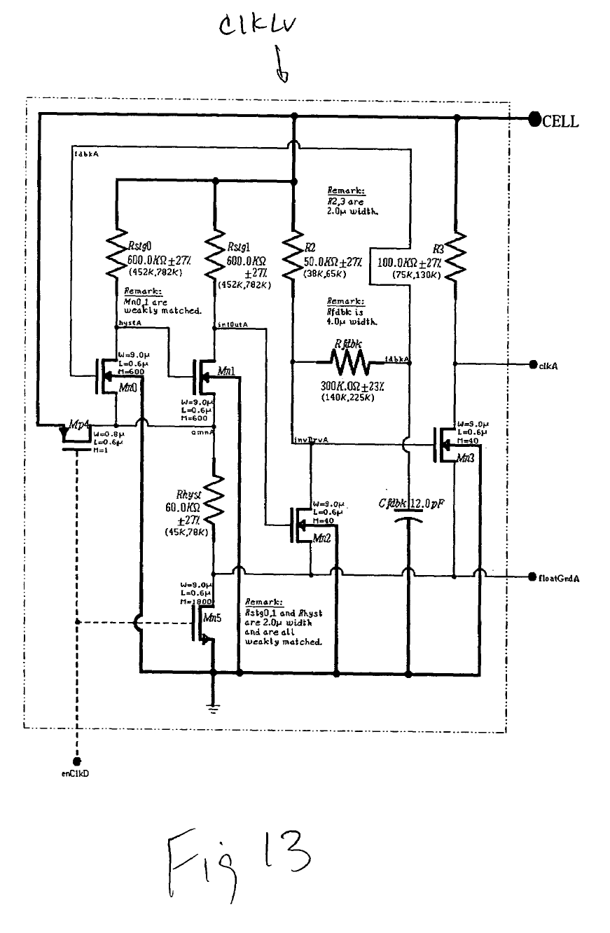

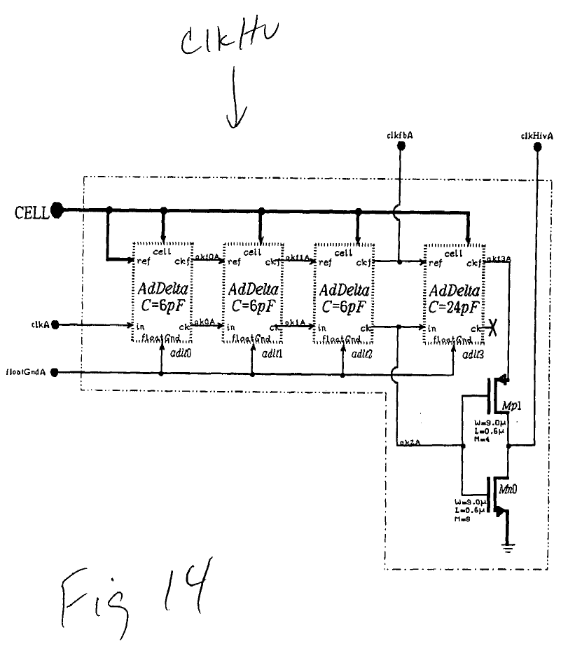

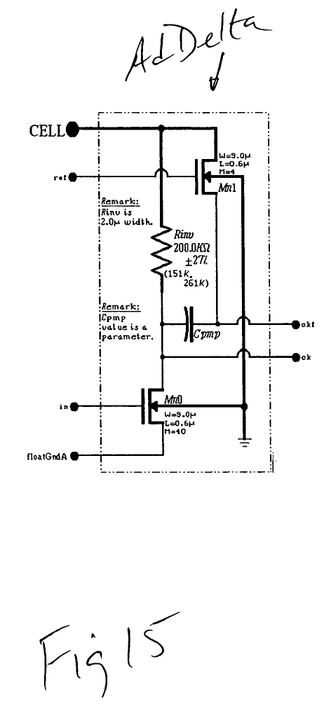

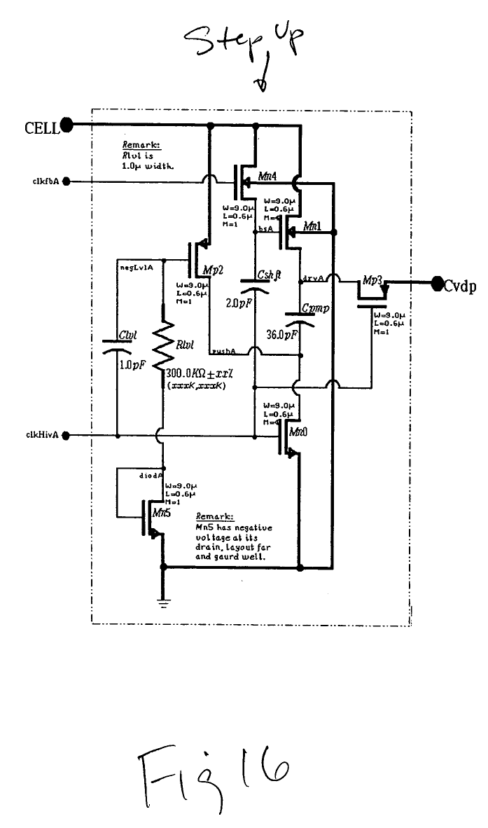

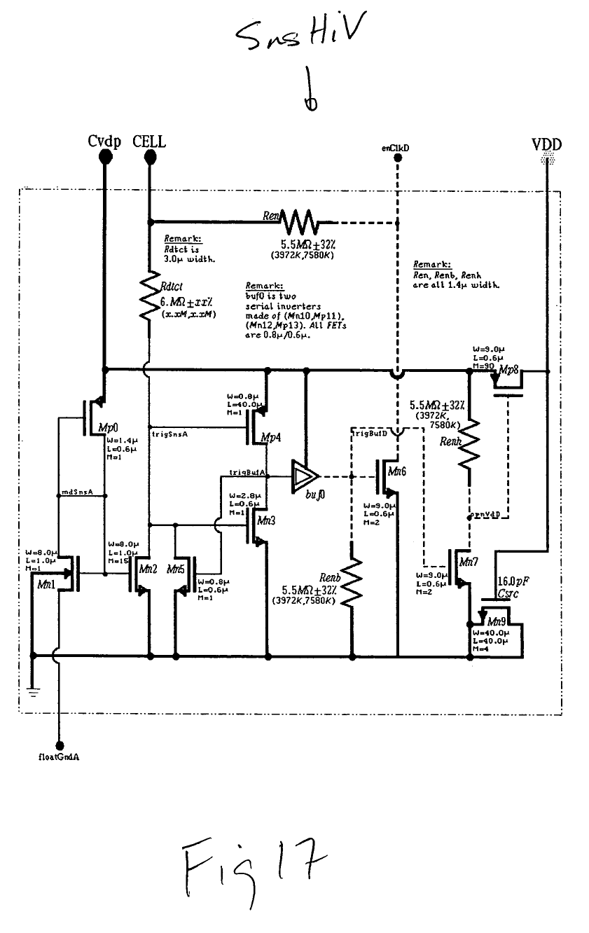

As shown, voltage boost converter 44 is composed of a ClkLv unit, a ClkHv unit, a StepUp unit, and snsHiV unit. An example of a ClkLv unit, which is shown in FIG. 13, is a low voltage clock generator designed to start working at cell source of 0.85V/1.0Ω. This clock generator can be, e.g., a hysterisis nMOSFET clock, and can incorporate a shutdown mode entered by enClkD=0. The ClkLv unit is checked to ensure operation of the cell within 0.82 V and 0.96 V, a serial resistance to the cell within a range of 0.1Ω and 1.0Ω, and a load of 100 fF. The measured parameter is the frequency of the clock. An exemplary embodiment of the ClkHv unit is illustrated in FIG. 14, and this unit takes the low voltage clock created by the ClkLv unit, floats it over a generated dc level created by internal AdDelta cells, which can have a capacitance of 6 pF or 24 pF, and converts the signal into a high voltage clock clkHivA output. An exemplary embodiment of an AdDelta cell is depicted in FIG. 15. The ClkHv unit also outputs the floating clock clkfbA, which has an inverted phase to clkHivA. It is note that the ClkHv unit is checked with ClkLv unit to ensure operation of the cell within 0.82 V and 0.96 V, a serial resistance to the cell within a range of 0.1Ω and 1.0Ω, and a load of 100 fF over clkfbA and a load of 1.2 pF over clkHivA, which the measured parameter is the positive voltage of cklHivA. The step up unit is shown, by way of example, in FIG. 16, as a charge pump that uses two (2) nMOSFETs to charge and two (2) pMOSFETs to discharge. As shown, ClvI stores negative voltage to enable conductance of Mp2 and Cshft stores positive voltage conducted by nMOSFET Mn4. The step up unit is checked with both ClkLv and ClkHv units for cell voltage in the range of 0.82 V and 0.96 V with a serial resistance to the cell in the range of 0.1Ω and 1.0Ω and a load of 1.0 nF. Further, the measured parameter at Cvdp is dc voltage. The final block of voltage boost converter 44, i.e., the SnsHiV unit, is shown in an exemplary fashion in FIG. 17. The SnsHiV unit looks for a Cvdp voltage of approximately VT(pMOS)+VT(nMOS). When such a voltage is detected, SnsHiV shuts down voltage boost converter 44 and shorts Vdd to Cvdp in order to set Vdd to a more suitable voltage. The SnsHiV unit is checked for cell voltage in a range of 0.82 V-0.96 V (with 200 mΩ serial resistance), and for a Cvdp voltage that will trigger the enClkD line.

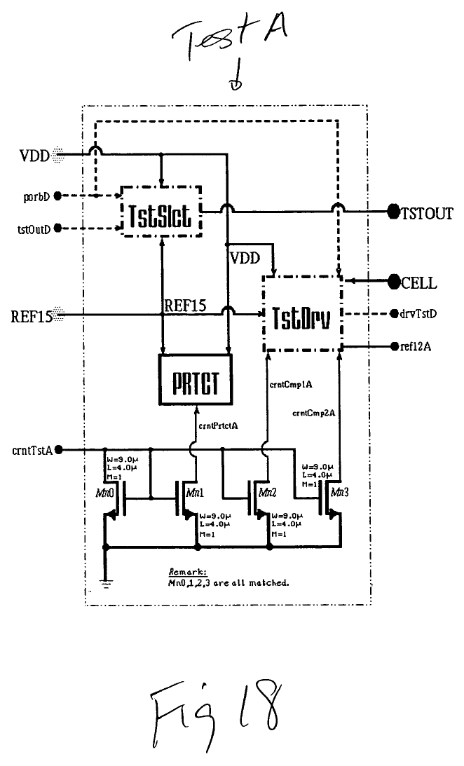

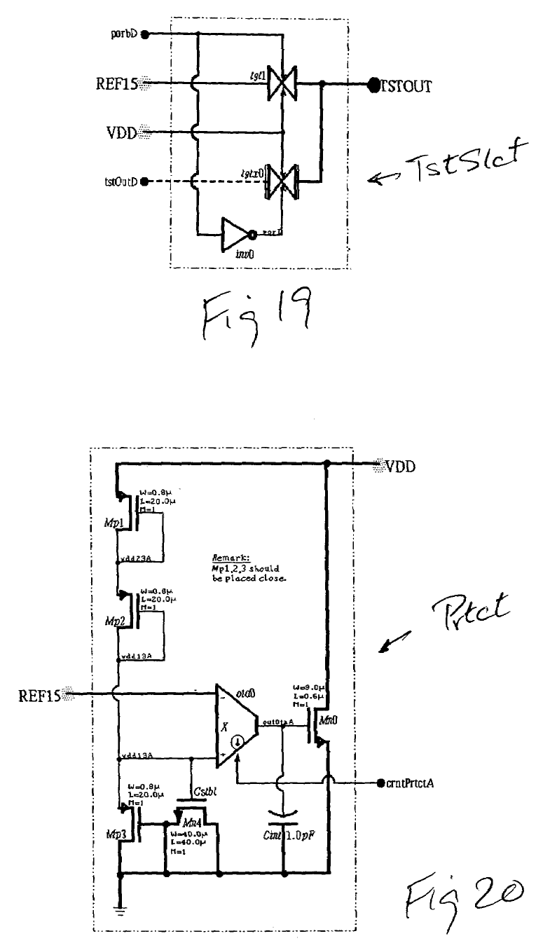

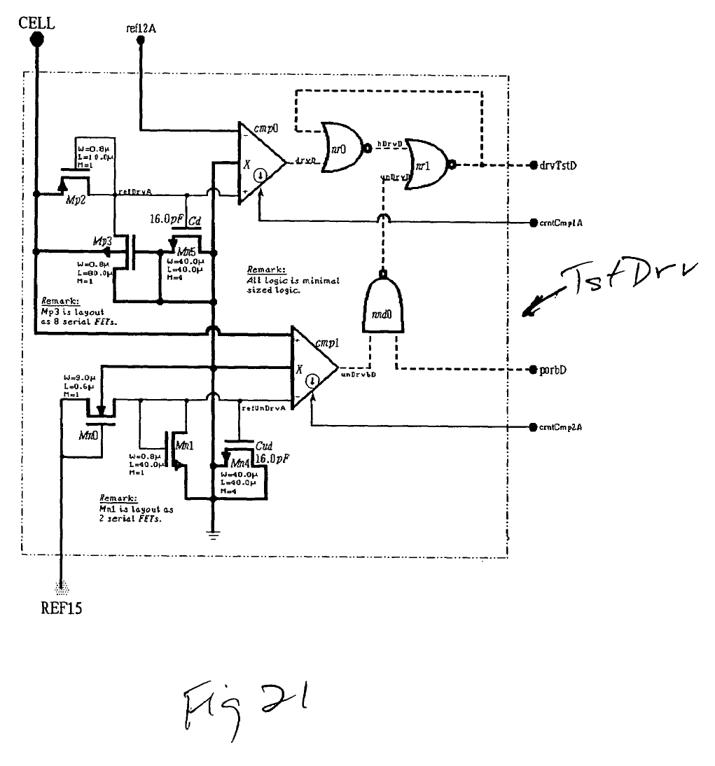

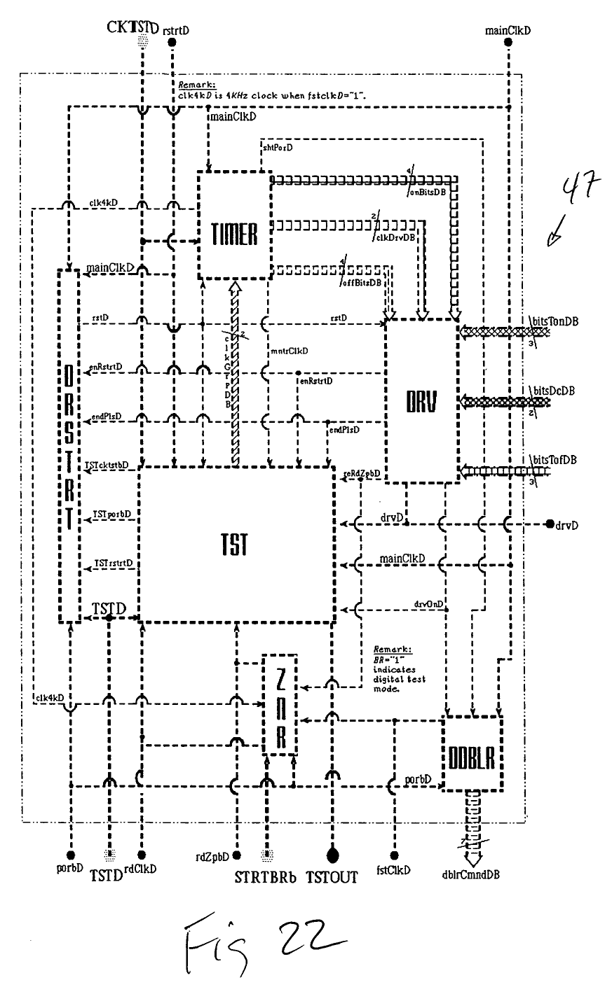

FIG. 18 illustrates an exemplary embodiment of test A unit 54. Test A unit 54 is composed of analog test parts, and preferably all analog test parts, and includes a test selector signal unit TstSlct, a drive test unit TstDrv, and a voltage protection unit Prtct. An exemplary embodiment of test selector signal unit TstSlct is shown in FIG. 19, in which the source of Tstout is selected according to the output of initializer 52 (porbD). An exemplary arrangement of voltage protection unit Prtct is depicted in FIG. 20, such that, during a test of the board connection, the voltage at the cell input may be, e.g., 2.3 V. As this voltage can create an overvoltage at Vdd, voltage protection unit 1103 is provided to limit Vdd to 4.5 V. Further, testing of the Prtct unit is done as part of a system simulation for all testing concepts. FIG. 21 shows an exemplary embodiment of the TstDrv unit, which detects voltage in excess of, e.g., 2.35 V±2% in the cell input, and which sets the system into production test mode. Testing for this unit will also be done as part of a system simulation for all testing concepts.

FIG. 22 schematically illustrates an exemplary embodiment for control 47 depicted in FIG. 4.

Moreover, it is contemplated that controller 40 can be integrated onto a single chip, which is either fixed or programmable, and can be built into or external to the fuel cell. Moreover, the chip on which controller 40 is integrated can include other controllers or converters.

It is noted that the foregoing examples have been provided merely for the purpose of explanation and are in no way to be construed as limiting of the present invention. While the present invention has been described with reference to an exemplary embodiment, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular means, materials and embodiments, the present invention is not intended to be limited to the particulars disclosed herein; rather, the present invention extends to all functionally equivalent structures, methods and uses, such as are within the scope of the appended claims.

What is claimed:

1. A process for controlling a fuel cell, comprising:
drawing a pulse from a fuel cell in one of a standby mode or no load condition, wherein the pulse is one of a power, current, and voltage pulse.

2. The process in accordance with claim 1, wherein, prior to the drawing of the pulse, the process further comprises:
determining one of a standby mode or no load condition;
starting a timer; and
upon the elapsing of a predetermined period, activating a timer to define the pulse to be drawn.

3. The process in accordance with claim 1, wherein, prior to the drawing of the pulse, the process further comprises:
determining one of a standby mode or no load condition;
measuring a voltage of the fuel cell; and
when the measured voltage is greater than a predetermined voltage, activating a timer to define the pulse to be drawn.

4. The process in accordance with claim 1, further comprising defining the pulse to be drawn as a single pulse followed by a rest period.

5. The process in accordance with claim 4, further comprising defining the pulse to be drawn as a plurality of sub-pulses nested within the single pulse.

6. The process in accordance with claim 1, wherein the fuel cell comprises a direct hydride fuel cell.

7. The process in accordance with claim 6, wherein the direct hydride fuel cell comprises a mesh membrane.

8. A controller for a fuel cell, comprising:
a field effect transistor arranged to selectively couple a resistance to fuel cell to draw current from the fuel cell; and
a timer defining a pulse, during which the field effect transistor couples the resistance to the fuel cell to draw current from the fuel cell.

9. The controller in accordance with claim 8, further comprising a control unit for monitoring for one of standby mode or no load condition in the fuel cell.

10. The controller in accordance with claim 9, further comprising a timing device coupled to said control unit, such that, when the one of a standby mode or no load condition is detected, a predetermined period of time is allowed to elapse before the timer defines the pulse.

11. The controller in accordance with claim 9, wherein the control device is structured for monitoring the voltage of the fuel cell.

12. The controller in accordance with claim 11, wherein, when the fuel cell voltage is greater than a predetermined voltage, the controller actuates the timer.

13. The controller in accordance with claim 1, wherein the controller is integrated onto a single chip.
